(19) United States
(12) Patent Application Publication
(10) Pub. No.: US 2006/0280973 A1
(43) Pub. Date: Dec. 14, 2006

(54) Tunable magnetic recording medium and its fabricating method

(76) Inventors: An-Cheng Sun, Taipei City (TW); Po-Cheng Kuo, Taipei City (TW); Jen-Hwa Hsu, Taipei City (TW); Huei-Li Huang, Taipei City (TW); Ching-Ray Chang, Taipei City (TW)

Correspondence Address: HARNESS, DICKEY & PIERCE, P.L.C., P.O. BOX 8910, RESTON, VA, 20195, US

(21) Appl. No.: 11/334,605

(22) Filed: Jan. 19, 2006

(30) Foreign Application Priority Data
Jun. 14, 2005 (TW) 094119723

(51) Int. Cl. G11B 5/66; C23C 14/00

(52) U.S. Cl. 428/831.2; 204/192.2

(57) ABSTRACT

A magnetic recording medium having at least an adjustable magnetic property is provided. The provided magnetic recording medium includes a substrate and a layer sequence located thereon. The layer sequence includes a underlayer, a buffer layer and a recording layer made of a magnetic material. According to the present invention, the adjustable magnetic property of the magnetic recording medium is adjusted via the variation of the thickness of the underlayer.

### FIELD OF THE INVENTION

The present invention relates to a recording medium and the fabrication method therefor, and more particularly to a magnetic recording medium and the fabrication method therefor.

### BACKGROUND OF THE INVENTION

The magnetic recording medium adopts the magnetic hysteresis character of the recording medium for data storage, where the digital data “0” and “1” to be stored are represented by the variation of magnetization of the recording medium.

In accordance with the direction of magnetic moment of the recording bit, the magnetic recording media are divided into two principal groups, namely the longitudinal recording media and the perpendicular recording media, where the longitudinal ones are much more popularized in the present applications. Regarding the longitudinal recording medium, the magnetic moment of the recording bit lies on the film surface. In this case, in order to increase the recording density of the medium, the bit size shall be further reduced, which always results in the increment of the demagnetization field, and thus the magnetic moment would be unstable. Accordingly, the written data would easily disappear due to the poor thermal stability, and the high recording density is hence unachievable.

As for the perpendicular recording medium, the magnetic moment of the recording bit is perpendicular to the film surface, and thus the recording particle would form as a column structure when the size of recording bit is reduced. Accordingly, the demagnetization field of the perpendicular recording medium is relatively low, so that the unstability of magnetic moment resulting from the size reduction of recording bit would be avoided. Therefore, the recorded data could be entirely retained in the medium.

For achieving the ultra-high recording density of up to 1 Tb/in², the magnetic recording medium needs to possess a high coercivity (H_{C}), a high saturation magnetization (Ms), an extremely high magnetocrystalline anisotropy constant (Kᵤ), a small grain size and a good ability in anti-corrosion. When the grain size of the magnetic material is reduced to less than 10 nm, the perpendicular recording medium would own a greater ability than the longitudinal recording one for overcoming the super-paramagnetic issue. In comparison with the longitudinal recording medium, therefore, the perpendicular recording one possesses a relatively great ability in improving the recording density. Nevertheless, owing to the difficulty in the improvement of the perpendicular recording technique, such as the design for the magnetic pole of magnetic head and for the distance between the magnetic head and the disk, the perpendicular recording medium still fails in popularization and commercialization in the recording application.

For overcoming the mentioned drawbacks of the conventional magnetic recording medium, a novel and improved tunable magnetic recording medium is provided. The provided magnetic recording medium includes a suitable underlayer as well as a buffer layer between the substrate and the recording layer, and utilizes the variation of thickness of the underlayer to adjust the magnetic properties of the magnetic recording medium and the crystalline orientation of the recording layer thereof. Through the present invention, the properties including the preferred orientation, the coercivity, the anisotropy, the easy axis and the hysteresis loop squareness of the fabricated magnetic recording medium are tunable by adjusting the thickness of the underlayer, so that such magnetic recording medium is more advantageous than the conventional ones in possessing the longitudinal and the perpendicular magnetic properties.

### SUMMARY OF THE INVENTION

In accordance with a first aspect of the present invention, a magnetic recording medium having at least an adjustable magnetic property is provided. The provided magnetic recording medium includes a substrate and a layer sequence located thereon. The layer sequence includes a underlayer, a buffer layer and a recording layer made of a magnetic material. According to the present invention, the adjustable magnetic property of the magnetic recording medium is adjusted via a variation of a thickness of the underlayer.

Preferably, each of the underlayer and the buffer layer is made of one selected from a group consisting of a metal, a first alloy, a compound, an oxide and a metallic salt.

Preferably, the metal is one selected from a group consisting of Fe, Co, Ni, Pt, Ag, Au, Cr, Pd, Cu, W, Ti, Ta, Nb, Mn, Ru and Mo.

Preferably, the first alloy is one selected from a group consisting of a metal-nonmetal alloy, a metal-metal alloy, a metal-semiconductor alloy and a metal-semimetal alloy.

Preferably, the metal-metal alloy is a Cr-based alloy.

Preferably, the Cr-based alloy is one selected from a group consisting of a CrRu alloy, a CrMo alloy, a CrW alloy and a CrTa alloy.

Preferably, the oxide is one of MgO and NiO.

Preferably, the metallic salt is NaCl.

Preferably, the variation of the thickness of said underlayer is ranged from 0.5 nm to 200 nm.

Preferably, the adjustable magnetic property is one selected from a group consisting of a preferred orientation, a coercivity, an anisotropy and a hysteresis loop squareness.

Preferably, the buffer layer has a thickness ranged from 0.2 nm to 80 nm.

Preferably, the magnetic material is a second alloy of a first material and a second material.

Preferably, the second alloy is one of a poly-crystalline alloy and a single-crystalline alloy.

Preferably, the first material is one of Fe and Co.

Preferably, the second material is one of Pt and Pd.

Preferably, the atomic composition ratio of the first material to the second alloy is ranged from 30% to 70%.

Preferably, the atomic composition ratio is ranged from 40% to 60%.

Preferably, the second alloy further includes at least a third material.

Preferably, the third material is one selected from a group consisting of Ag, Au, Cr, Cu, W, Ti, Ta, Nb, Mn, Mo, Zr, V, C, B, Zn, Ru, P and N.

Preferably, the recording layer has a thickness ranged from 3 nm to 100 nm.

Preferably, the recording layer has a saturation magnetization ranged from 100 to 1500 emu/cm³.

In accordance with a second aspect of the present invention, a recording medium having at least a recording property is provided. The provided recording medium includes a substrate, an adjustment layer located on the substrate for adjusting the recording property, and a recording layer located on the adjustment layer.

According to the second aspect, the recording medium further includes a buffer layer located between the adjustment layer and the recording layer.

Preferably, the adjustment layer is made of one selected from a group consisting of a metal, a first alloy, a compound, an oxide and a metallic salt.

Preferably, the adjustment layer has a thickness ranged from 0.5 nm to 200 nm.

Preferably, the recording property is one selected from a group consisting of a preferred orientation, a coercivity, an anisotropy and a hysteresis loop squareness.

Preferably, the coercivity is ranged from 1000 Oe to 25000 Oe.

Preferably, the hysteresis loop squareness is ranged from 0.5 to 1.

In accordance with a third aspect of the present invention, a method for fabricating a recording medium is provided, which includes steps of (a) providing a substrate, (b) forming a property-deciding layer of a specific parameter on the provided substrate, (c) forming a buffer layer on the property-deciding layer, and (d) forming a recording layer on the buffer layer.

Preferably, the step (b) is performed by sputtering under a first temperature ranged from 20° C. to 800° C.

Accordingly, the first temperature is preferably ranged from 300° C. to 350° C.

Preferably, the step (c) is performed by sputtering under a second temperature ranged from 25° C. to 800° C.

Accordingly, the second temperature is preferably ranged from 300° C. to 350° C.

Preferably, the step (d) is performed by sputtering under a third temperature ranged from 100° C. to 800° C.

Accordingly, the third temperature is preferably ranged from 250° C. to 450° C.

Preferably, the specific parameter is a thickness.

The foregoing and other features and advantages of the present invention will be more clearly understood through the following descriptions with reference to the drawings, wherein:

### BRIEF DESCRIPTION OF THE DRAWINGS

FIG. 1 is a flow chart illustrating the process for fabricating the tunable magnetic recording medium according to a preferred embodiment of the present invention;

FIG. 2 is a cross-sectional view schematically showing the fabricated tunable magnetic recording medium according to the preferred embodiment of the present invention;

FIGS. 3(a) to 3(h) are diagrams showing the respective hysteresis loops for the magnetic recording media according to the first to the eighth embodiments of the present invention;

FIG. 4 is a diagram illustrating the relationship between the hysteresis loop squareness (S_{//} and S_{⊥}) of the magnetic recording medium and the thickness of the Cr underlayer thereof and the relationship between the coercivity (H_{C}_{^{⊥}}) of the magnetic recording medium and the thickness of the Cr underlayer thereof;

FIG. 5 is an X-ray diffraction pattern illustrating the relationship between the microstructure variation of FePt/Pt/Cr layer sequence of the magnetic recording medium and the thickness of the Cr underlayer thereof; and

FIG. 6 is a diagram schematically illustrating the atom arrangement at the interface of the FePt/Pt/Cr layer sequence.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

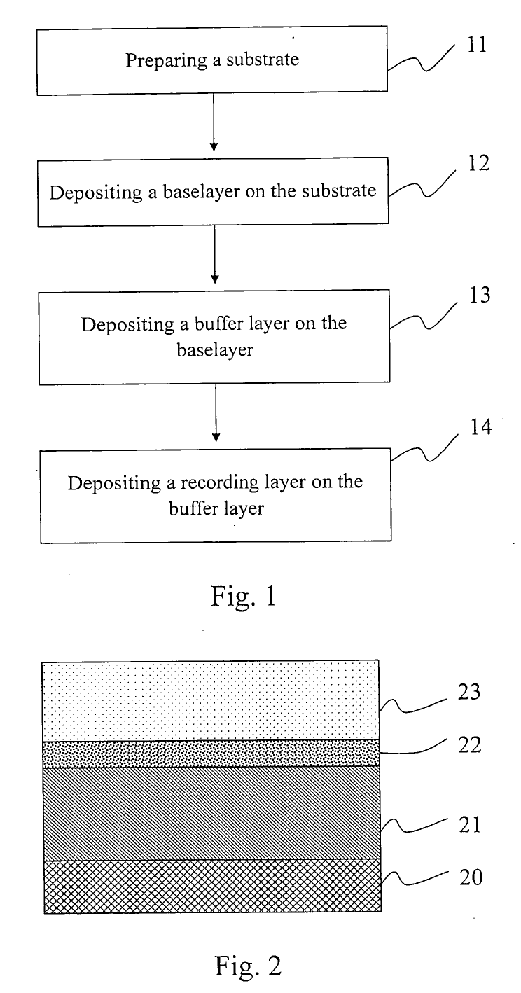

The fabrication method for the tunable magnetic recording medium according to the present invention is illustrated with reference to FIG. 1.

Please refer to FIG. 1, which is a flow chart schematically illustrating the process for fabricating the tunable magnetic recording medium according to a preferred embodiment of the present invention. First, a substrate is prepared, as shown in the step 11. The underlayer, i.e. the adjustment layer, of a specific thickness is formed on the prepared substrate, as shown in the step 12. The buffer layer is subsequently formed on the adjustment layer, as shown in the step 13. Afterward, the recording layer is formed on the buffer layer and the tunable magnetic recording medium according to the present invention is thus fabricated, as shown in the step 14.

In more specifics, according to a preferred embodiment of the present invention, a water-cooling ultra-high vacuum sputtering system is designed for the film deposition, so as to produce the layer sequence of the magnetic recording medium. The adjustment layer and the buffer layer are respectively deposited by sputtering at a first and a second temperature, where both of the first temperature and the second temperature are ranged from 20° C. to 800° C., and preferably, from 300° C. to 350° C. Moreover, the recording layer is deposited on the buffer layer by sputtering at a third temperature ranged from 100° C. to 800° C., and preferably, from 250° C. to 450° C.

The present invention adopts the underlayer of a specific thickness as the adjustment layer for the magnetic recording medium, so as to adjust or tune the preferred orientation, the coercivity, the anisotropy and the hysteresis loop squareness thereof. The underlayer may be made of metal, such as Fe, Co, Ni, Pt, Ag, Au, Cr, Pd, Cu, W, Ti, Ta, Nb, Mn, Ru or Mo, may be made of oxides, such as MgO or NiO, and may be made of NaCl, where the thickness thereof is ranged from 0.5. to 200 nm.

The buffer layer is made of metal, such as Fe, Co, Ni, Pt, Ag, Au, Cr, Pd, Cu, W, Ti, Ta, Nb, Mn, Ru or Mo, where the thickness thereof is ranged from 0.2 to 80 nm.

In the present invention, the recording layer is a poly-crystalline alloy or a single-crystalline alloy composed of a first metal and a second metal. In a preferred embodiment, the first metal is Fe or Co, and the atomic composition thereof is ranged from 30% to 70% and preferably, 40% to 60%. The second metal of the recording layer is Pt or Pt. Moreover, the recording layer may include a further material of such as Ag, Au, Cr, Cu, W, Ti, Ta, Nb, Mn, Mo, Zr, V, C, B, Zn, Ru, P or N. Preferably, the thickness of the recording layer is ranged from 3 nm to 100 nm, where the saturation magnetization falls in a range of 100 to 1500 emu/cm³.

The following example is provided for specifically illustrating the present invention in more detailed. In this embodiment, a silicon substrate as well as a Corning 7059 glass is adopted for the substrate of the present magnetic recording medium, and a layer sequence of Cr, Pt and FePt are provided thereon for serving as the underlayer, i.e. the adjustment layer, the buffer layer and the recording layer, respectively.

First, the substrate is cleaned with acetone and alcohol. The cleaned substrate is loaded into the vacuum chamber of the sputtering system. For sufficiently removing the attached contaminants including the mist, oxygen and nitrogen from the substrate, an RF pre-sputtering process for a further complete cleaning needs to be performed thereon. The pre-sputtering process includes the following procedures:

(1) loading the substrate into an additional chamber of the sputtering system, and extracting the air therein so as to achieve a pressure of less than 10-7 Torr;

(2) introducing the Ar gas into the additional chamber, and maintaining the pressure on 10 mTorr;

(3) switching on the RF generator, where the output power is controlled as 20 W, so as to clean the surface of the substrate with the Ar gas;

(4) loading the cleaned substrate into the vacuum chamber of the sputtering system;

(5) keeping extracting the air from the vacuum chamber for about 30 to 60 minutes, so as to lower down the pressure thereof; and

(6) proceeding the sputtering process when the pressure of the vacuum chamber is below 5×10⁻⁹ Torr.

Subsequently, the desired layer sequence is deposited on the cleaned substrate, where the deposition procedures are illustrated as follows:

(1) heating the substrate to achieve a temperature of 350° C. and keeping the substrate at such temperature for 20 minutes, so as to make the substrate to be uniformly heated;

(2) introducing the Ar gas to the vacuum chamber and keeping the pressure thereof at 5 mTorr;

(3) when the Ar pressure is stabilized, depositing the Cr underlayer on the substrate with a Cr target where the deposition conditions therefor include a DC power of 100 W, a biased voltage of −200V and a rotation rate of the carrier of 10 rpm;

(4) shuttering the Cr target and switching off the DC power, and then controlling the Ar pressure to achieve 10 mTorr and keeping the substrate at a temperature of 350° C.;

(5) when the Ar pressure is stabilized, depositing a Pt buffer layer of 2 nm onto the Cr underlayer with a Pt target;

(6) shuttering the Pt target and switching off the DC power, and then heating the substrate to achieve a temperature of 450° C. and keeping the Ar pressure at a pressure of 10 mTorr; and

(7) when the Ar pressure is stabilized, co-depositing a FePt recording layer onto the Pt buffer layer with the Fe target and the Pt taget, where the thickness of the FePt recording layer is 20 nm, so that the present magnetic recording medium is fabricated.

When the mentioned deposition procedures are finished, the Fe target and the Pt target are shuttered and the DC power is switched off. Moreover, the quartz heater of the sputtering system is also turned off at an Ar pressure of 10 mTorr. The fabricated magnetic recording medium is loaded out from the vacuum chamber when the temperature thereof is lowered down to 100° C., so as to prevent the layer sequence deposited on the substrate from thermal oxidization while exposing to the atmosphere.

Please refer to FIG. 2, which is a cross-sectional view schematically showing the fabricated tunable magnetic recording medium according to the preferred embodiment of the present invention. The magnetic recording medium includes a substrate 20, which is a silicon substrate or a Corning 7059 substrate. On the substrate 20, there is a layer sequence including a underlayer 21, a buffer layer 22, and a recording layer 23 formed. In this embodiment, preferably, the underlayer is a Cr layer, the buffer layer is a Pt layer, and the recording layer is made of FePt.

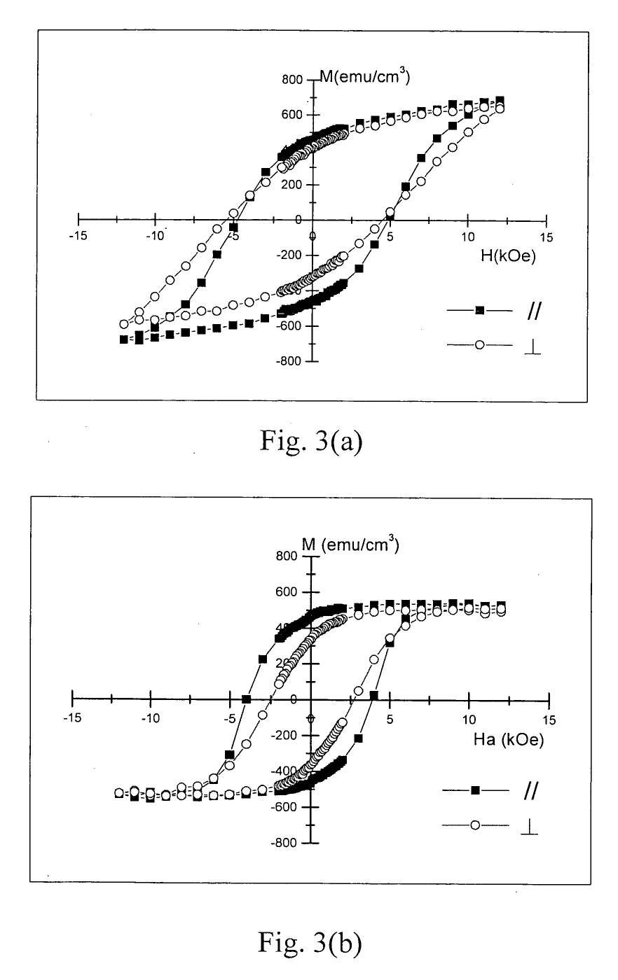

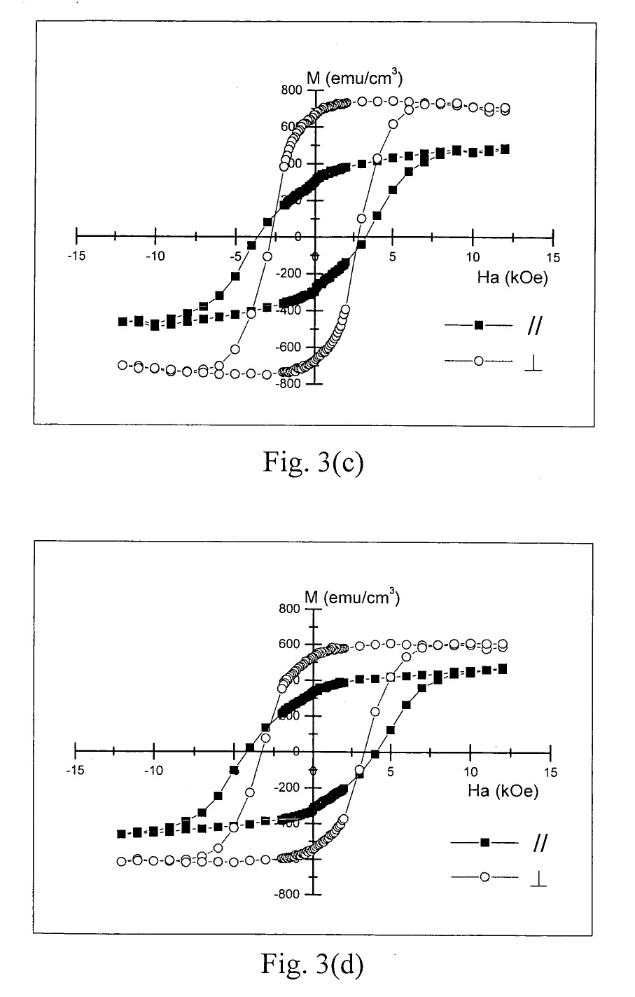

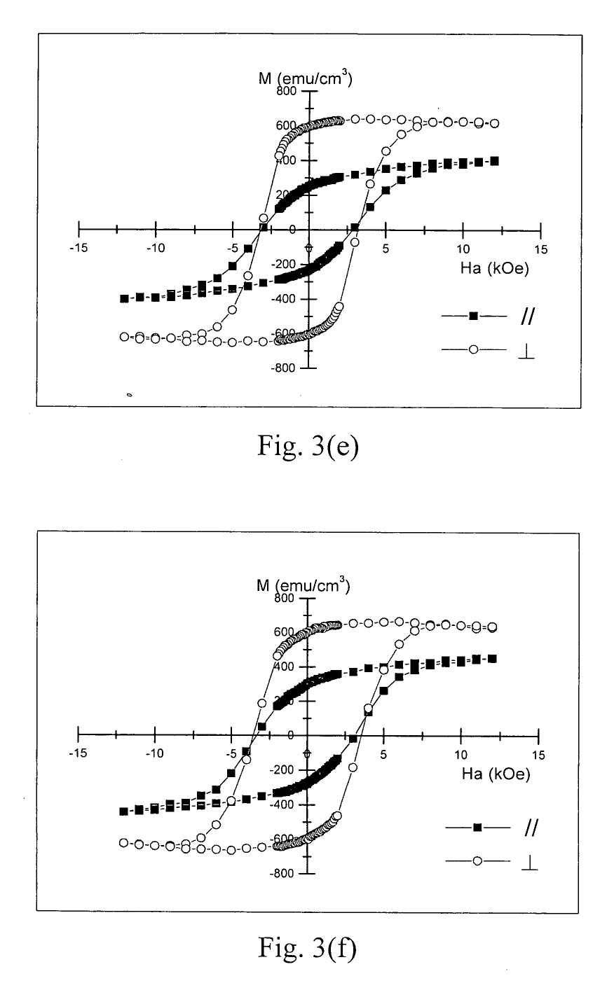

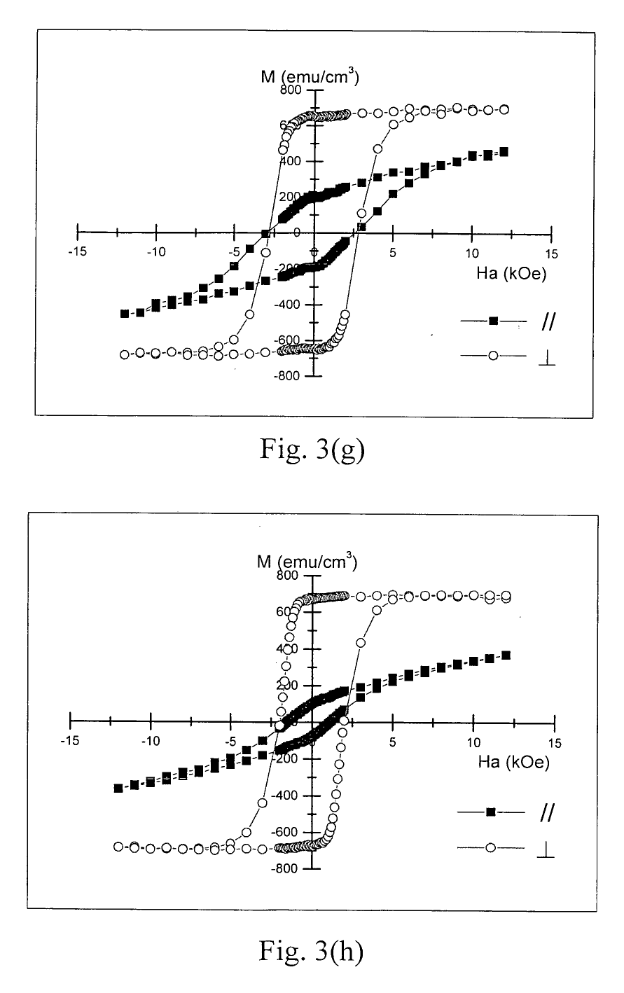

Please refer to FIGS. 3(a) to 3(h), which are diagrams showing the respective hysteresis loops for the magnetic recording media according to the first to the eighth embodiments of the present invention.

In these embodiments, the magnetic recording layer having a layer sequence of FePt/Pt/Cr as the respective recording layer/buffer layer/underlayer is fabricated under the fabrication method of the present invention, where the thickness of the FePt recording is 20 nm, the thickness of the Pt buffer layer is 2 nm, and the thickness of the Cr underlayer is 0, 10, 20, 30, 50, 70, 90 and 110 nm, respectively. The respective magnetic hysteresis loop of the fabricated magnetic recording medium is shown in FIGS. 3(a) to 3(h).

With reference to FIGS. 3(a) to 3(h), the respective magnetic hysteresis loop of the fabricated magnetic recording medium is shown, where the x-axis and the y-axis thereof represent the magnitude of the applied magnetic field H (kOe) and the corresponding saturation magnetization M (emu/cm³), respectively. In these diagrams, the reference numeral -▪- represents the longitudinal (//) magnetic property of the magnetic recording medium, and the reference numeral -∘- represnets the perpendicular (⊥) magnetic property of the magnetic recording medium. The mentioned figures reveal that when the thickness of the Cr underlayer is less than 20 nm, the longitudinal squareness S_{//} is higher than the perpendicular one S₁₉₅ , and thus the magnetci recording mediun exhibits the longitudinal magnetic properties, as shown in FIGS. 3(a) and 3(b). When the thickness of the Cr underlayer is increased to more than 20 nm, the longitudinal squareness S_{//} would be lower than the perpendicular one S_{⊥}, which results in the perpendicular magnetic properties of the magnetic recording medium. Furthermore, with the thickness of the Cr underlayer increasing, the perpendicular squareness S_{⊥} would approach to the value 1, as shown in FIGS. 3(c) to 3(h).

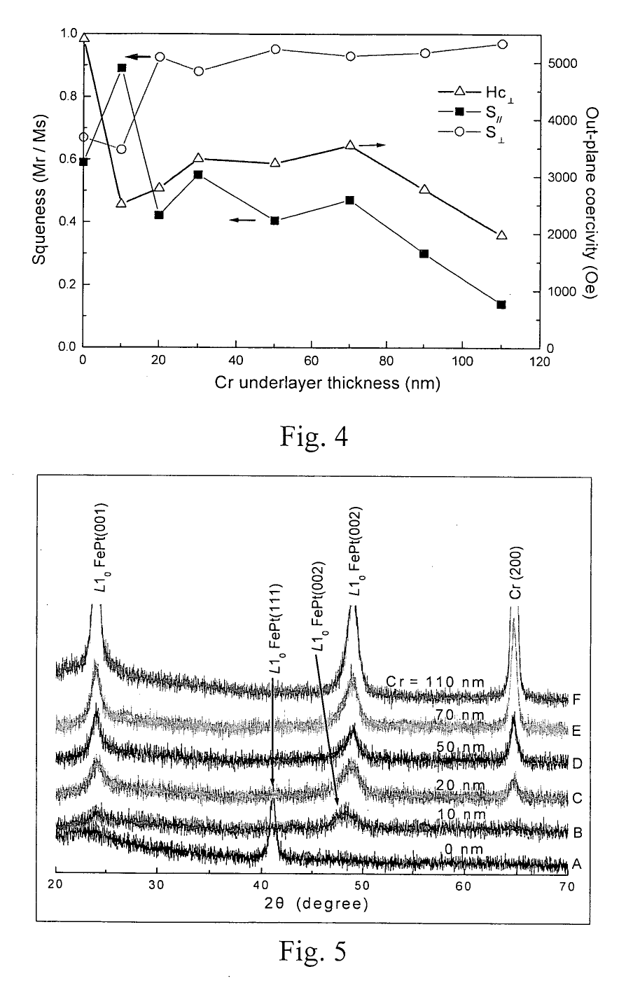

Please refer to FIG. 4 illustrating the relationship between the hysteresis loop squareness (S_{//} and S_{⊥}) of the magnetic recording medium and the thickness of the Cr underlayer thereof and the relationship between the coercivity (H_{C}_{_{⊥}}) of the magnetic recording medium and the thickness of the Cr underlayer thereof, where the x-axis of the diagram represents the thickness of the Cr underlayer, and two lateral axes thereof represent the squareness S and the coercivity H_{C}, in which S is defined as Mr/Ms. In FIG. 4, the reference numeral -Δ- represents the coercivity H_{C}_{_{⊥}} and the reference numerals -▪- and -∘- represent the longitudinal squareness S_{//} and the perpendicular squareness S_{⊥} of the magnetic recording medium, respectively.

As shown in FIG. 4, when the thickness of the Cr underlayer is 10 nm, the magnetic recording medium would exhibit the longitudinal magnetic properties, where the longitudinal squareness S_{//} thereof is about 0.9. Moreover, when the thickness of the Cr underlayer is increased to 20 nm, the perpendicular squareness S_{⊥} thereof would approach to more than 0.9, and the magnetic recording medium would begin to exhibit the perpendicular magnetic properties. With the thickness of the Cr underlayer increasing, the longitudinal squareness S_{//} would gradually decrease. Furthernore, when the thickness of the Cr underlayer is increased to 110 nm, the longitudinal squareness S_{//} would decrease to about 0.15, showing that the longitudinal magnetic anisotropy of the fabricated magnetic recording medium would be suppressed while the thickness of the underlayer is increased.

Furthermore, FIG. 4 also reveals that the coercivity H_{C}_{_{⊥}} in the direction perpendicular to the film surface of the magnetic recording medium would vary with the variation of the thickness of Cr underlayer, and the magnetic recording medium would exhibit a highest perpendicular coercivity H_{C}_{_{⊥}}, i.e. about 3600 Oe, when the thickness of the Cr underlayer is 70 nm. In this case, the perpendicular coercivity of the magnetic recording medium increases with the thickness of the Cr underlayer thereof increasing when the thickness of the Cr underlayer is less than 70 nm, and decreases with the thickness of the Cr underlayer thereof increasing when the thickness of the Cr underlayer is more than 70 nm. Specifically, the perpendicular coercivity H_{C}_{_{⊥}} would be less than 2000 Oe, when the thickness of the Cr underlayer achieves to 110 nm.

Please refer to FIG. 5, which is an X-ray diffraction pattern illustrating the relationship between the microstructure variation of FePt/Pt/Cr layer sequence of the magnetic recording medium and the thickness of the Cr underlayer thereof. It reveals that there is only a peak (111) of L1₀ FePt phase existing in the diffraction pattern the layer sequence of the magnetic recording medium does not include a Cr underlayer. In this case, the deposited FePt recording layer would epitaxially grow in the direction (111) of the Pt buffer layer, and thus exhibit the property of single-crystalline FePt (111), as shown in Pattern A of FIG. 5. When the Cr underlayer is added into the layer sequence of the magnetic recording medium, the peak (111) of L1₀ FePt phase disappears, while other peaks of L1₀ FePt phase begin to appear. As shown in Pattern B of FIG. 5, when the thickness of the Cr underlayer is 10 nm, the (001) peak of L1₀ FePt phase is weak, while the (200) one is much intensive. It shows that the easy axis [001] of the L1₀ FePt phase lies on the film surface, and the FePt/Pt/Cr layer sequence would exhibit its longitudinal magnetic properties. When the thickness of the Cr underlayer is 20 nm, as shown in Pattern C of FIG. 5, L1₀ FePt(200)switches to the high orientation L1₀ FePt(002), and the intensity of the (001) peak is also enhanced. It shows that the easy axis [001] of the L1₀ FePt phase is perpendicular to the film surface, and thus the FePt/Pt/Cr layer sequence would exhibit its perpendicular magnetic anisotropy. With the thickness of the Cr underlayer increasing, the crystallization of Cr (200) would be enhanced, and thus the (001) peak of L1₀ FePt phase is further enhanced, as shown in Patterns D, E and F of FIG. 5. In this case, the FePt/Pt/Cr layer sequence would exhibit its perpendicular magnetic anisotropy.

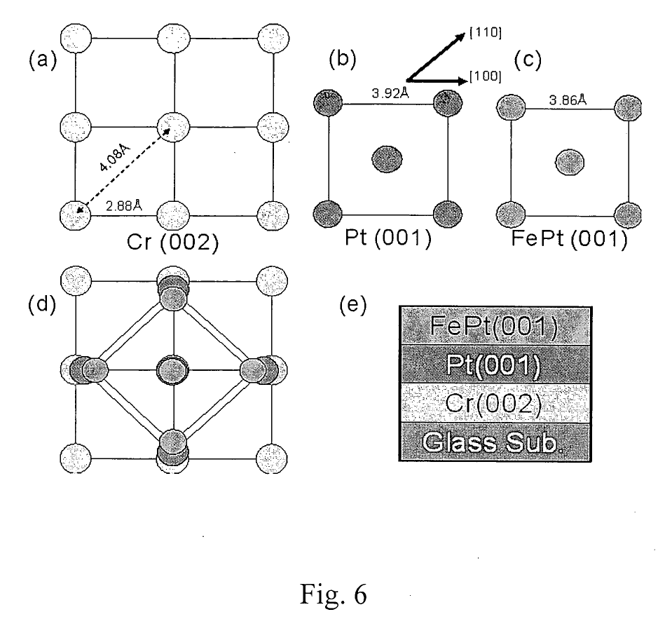

Please refer to FIG. 6, showing the atom arrangement at the interface of the FePt/Pt/Cr layer sequence, which also schematically illustrates why the FePt/Pt/Cr layer sequence of the magnetic recording medium according to the present invention exhibits the perpendicular magnetic anisotropy. Fig. (a) shows the (002) face of the bcc Cr, where the lattice parameter thereof is 2.88 Å and the length of diagonal axis [110] thereof is 4.08 Å. Fig. (b) shows the (001) face of Pt, where the lattice parameter thereof is 3.92 Å, and Fig. (c) shows the (001) face of FePt, where the lattice parameter thereof is 3.86 Å. Fig. (d) is a top view showing the atom arrangement at the interface of the FePt/Pt/Cr layer sequence, and Fig. (e) shows the structure of the layer sequence. In addition, the arrows in Fig. (b) represent the [100] direction and the [110] direction of the lattice, respectively.

Based on the mentioned descriptions, since there is a misfit of about 4.1% existing between the length of diagonal axis [110] of the (002) face of the bcc Cr and the (001) [100] axis of the Pt layer, the Pt layer would grow in the (002) face of the Cr underlayer as the (001) orientation. In comparison with the conventional magnetic recording medium having a FePt recording layer, the tunable magnetic recording medium according to the present invention adopts a Cr underlayer of a specific thickness for being the adjustment layer, so that the FePt recording layer deposited thereon would grow along the (002) face thereof, so as to provide a recording layer with the (001) orientation, i.e. the perpendicular anisotropy, therefor. In addition, when the thickness of the Cr underlayer is less than 20 nm, bringing a poor crystallization in the (002) face, the Pt buffer layer deposited thereon would lose its (001) orientation, so that the easy axis of the FePt recording layer tends to lie in the direction parallel to the film surface, and thus the magnetic recording medium exhibit the longitudinal magnetic anisotropy. Accordingly, by adjusting the thickness of the Cr underlayer, the various magnetic properties including the easy axis of the magnetic recording medium, the magnetic anisotropy thereof, the saturation magnetization thereof, the coercivity and the squareness of the magnetic hysteresis loop thereof are all easily adjustable. In more specifics, the easy axis of the magnetic recording medium as well as the magnetic anisotropy thereof are adjusted to be the direction parallel or perpendicular to the film surface, and the magnitudes of the saturation magnetization, the coercivity and the squareness of the magnetic hysteresis loop thereof are also adjustable in a range of 100˜1500 emu/cm³, 1000˜25000 Oe and 0.5˜1, respectively. The magnetic recording medium according to the present invention is advantageous in the mentioned improvements that are not achievable by the conventional ones.

Therefore, the present invention not only has the novelty and the progressiveness, but also has an industry utility.

While the invention has been described in terms of what is presently considered to be the most practical and preferred embodiment, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A magnetic recording medium having at least an adjustable magnetic property, comprising:
a substrate;
a underlayer located on said substrate;
a buffer layer located on said underlayer; and
a recording layer made of a magnetic material and located on said buffer layer,
wherein said adjustable magnetic property is adjusted via a variation of a thickness of said underlayer.

2. The magnetic recording medium according to claim 1, wherein each of said underlayer and said buffer layer is made of one selected from a group consisting of a metal, a first alloy, a compound, an oxide and a metallic salt.

3. The magnetic recording medium according to claim 2, wherein said metal is one selected from a group consisting of Fe, Co, Ni, Pt, Ag, Au, Cr, Pd, Cu, W, Ti, Ta, Nb, Mn, Ru and Mo.

4. The magnetic recording medium according to claim 2, wherein said first alloy is one selected from a group consisting of a metal-nonmetal alloy, a metal-metal alloy, a metal-semiconductor alloy and a metal-semimetal alloy.

5. The magnetic recording medium according to claim 4, wherein said metal-metal alloy is a Cr-based alloy.

6. The magnetic recording medium according to claim 5, wherein said Cr-based alloy is one selected from a group consisting of a CrRu alloy, a CrMo alloy, a CrW alloy and a CrTa alloy.

7. The magnetic recording medium according to claim 2, wherein said oxide is one of MgO and NiO.

8. The magnetic recording medium according to claim 2, wherein said metallic salt is NaCl.

9. The magnetic recording medium according to claim 1, wherein said variation of said thickness of said underlayer is ranged from 0.5 nm to 200 nm.

10. The magnetic recording medium according to claim 1, wherein said adjustable magnetic property is one selected from a group consisting of a preferred orientation, a coercivity, an anisotropy and a hysteresis loop squareness.

11. The magnetic recording medium according to claim 1, wherein said buffer layer has a thickness ranged from 0.2 nm to 80 nm.

12. The magnetic recording medium according to claim 1, wherein said magnetic material is a second alloy of a first material and a second material.

13. The magnetic recording medium according to claim 12, wherein said second alloy is one of a poly-crystalline alloy and a single-crystalline alloy.

14. The magnetic recording medium according to claim 12, wherein said first material is one of Fe and Co.

15. The magnetic recording medium according to claim 12, wherein said second material is one of Pt and Pd.

16. The magnetic recording medium according to claim 12, wherein an atomic composition ratio of said first material to said second alloy is ranged from 30% to 70%.

17. The magnetic recording medium according to claim 16, wherein said atomic composition ratio is ranged from 40% to 60%.

18. The magnetic recording medium according to claim 12, wherein said second alloy further comprises at least a third material.

19. The magnetic recording medium according to claim 18, wherein said third material is one selected from a group consisting of Ag, Au, Cr, Cu, W, Ti, Ta, Nb, Mn, Mo, Zr, V, C, B, Zn, Ru, P and N.

20. The magnetic recording medium according to claim 1, wherein said recording layer has a thickness ranged from 3 nm to 100 nm.

21. The magnetic recording medium according to claim 1, wherein said recording layer has a saturation magnetization ranged from 100 emu/cm³ to 1500 emu/cm³.

22. A recording medium having at least a recording property, comprising:
a substrate;
an adjustment layer located on said substrate for adjusting said recording property; and
a recording layer located on said adjustment layer.

23. The recording medium according to claim 22, further comprising a buffer layer located between said adjustment layer and said recording layer.

24. The recording medium according to claim 22, wherein said adjustment layer is made of one selected from a group consisting of a metal, a first alloy, a compound, an oxide and a metallic salt.

25. The recording medium according to claim 22, wherein said adjustment layer has a thickness ranged from 0.5 nm to 200 nm.

26. The recording medium according to claim 22, wherein said recording property is one selected from a group consisting of a preferred orientation, a coercivity, an anisotropy and a hysteresis loop squareness.

27. The recording medium according to claim 26, wherein said coercivity is ranged from 1000 Oe to 25000 Oe.

28. The recording medium according to claim 26, wherein said hysteresis loop squareness is ranged from 0.5 to 1.

29. A method for fabricating a recording medium, comprising steps of:
(a) providing a substrate;
(b) forming a property-deciding layer of a specific parameter on said substrate;
(c) forming a buffer layer on said property-deciding layer; and
(d) forming a recording layer on said buffer layer.

30. The method according to claim 29, wherein said step (b) is performed by sputtering under a first temperature ranged from 20° C. to 800° C.

31. The method according to claim 30, wherein said first temperature is preferably ranged from 300° C. to 350° C.

32. The method according to claim 29, wherein said step (c) is performed by sputtering under a second temperature ranged from 25° C. to 800° C.

33. The method according to claim 32, wherein said second temperature is preferably ranged from 300° C. to 350° C.

34. The method according to claim 29, wherein said step (d) is performed by sputtering under a third temperature ranged from 100° C. to 800° C.

35. The method according to claim 34, wherein said third temperature is preferably ranged from 250° C. to 450° C.

36. The method according to claim 29, wherein said specific parameter is a thickness.
